(19) United States
(12) Patent Application Publication
(10) Pub. No.: US 2026/0302915 A1
(43) Pub. Date: Oct. 1, 2026

(54) CONTROL SYSTEM AND CONTROL METHOD THEREOF

(71) Applicant: Delta Electronics, Inc., Taoyuan City (TW)

(72) Inventors: Ke Sun, Shanghai (CN); Shaopeng Han, Shanghai (CN); Yanbing Xia, Shanghai (CN)

(21) Appl. No.: 19/568,620

(22) Filed: Mar. 16, 2026

(30) Foreign Application Priority Data
Apr. 1, 2025 (CN) 202510404766.4

(51) Int. Cl. H02M 1/00; G01R 19/00; H02M 3/00; H02M 3/335

(52) U.S. Cl. CPC H02M 1/0032; G01R 19/0053; H02M 3/01; H02M 3/33507; H02M 3/3353

(57) ABSTRACT

A control system and a control method are provided. The converter has a low-load gain curve, a high-load gain curve, a preset low-load operating frequency and a preset high-load operating frequency according to characteristics of the converter. The detection module samples the output voltage of the converter and an electrical signal. The electrical signal is a sampled signal reflecting an actual load value of the load. The control module adjusts the output voltage of the converter according to the electrical signal and a gain variation coefficient and output a control signal to adjust an operating frequency of the converter. A difference between a full-load operating frequency and a no-load operating frequency of the converter is less than a first preset frequency difference. The gain variation coefficient is determined according to the low-load gain curve, the high-load gain curve, the preset low-load operating frequency and the preset high-load operating frequency.

### CROSS-REFERENCE TO RELATED APPLICATION

This application claims the priority to China Patent Application No. 202510404766.4 filed on Apr. 1, 2025, the entirety of which is hereby incorporated by reference.

### FIELD OF THE INVENTION

The present disclosure relates to power system, and more particularly to a control system and a control method of the control system.

### BACKGROUND OF THE INVENTION

At present, power supply systems are developing toward modularization, high-frequency operation and digitalization. The LLC circuit of the power supply system achieves zero-voltage switching across the full load range. The LLC circuit has advantages of reducing switching loss, enhancing efficiency and reducing size. Consequently, the LLC circuit has been widely applied. The LLC circuit is controlled through digital signal processing and has a wide gain range. However, during switching between no-load condition and full-load condition, the operating frequency varies significantly. Consequently, the operation of the converter within the power supply system is unstable. Moreover, the converter is controlled by digital signal processing. Loop delays such as sampling delay are introduced. Consequently, the operating frequency of the converter is changed slowly during dynamic load variations, so that dynamic response of the converter is reduced. In order to address the foregoing issues, the conventional power supply system introduces the operating current of the converter into the control loop to adjust the gain of the converter. Consequently, the operating frequency variation range of the LLC circuit is reduced during transitions between no-load condition and full-load condition. Meanwhile, the response speed of the converter during dynamic load variations is improved.

At present, converters adopt two types of operating frequency regulation methods. The first method is referred to as a direct modulation method. In first method, during load transitions, a period variation amount is determined by either table lookup or calculation according to the output current before and after the load transition. The period variation amount is added onto a linear controller to achieve rapid adjustment of the operating frequency. However, the first method requires accurate modeling of the converter and requires the switching period to be calculated according to the cycle. The requirements on the controller are enhanced. Furthermore, when the variation range of the operating frequency is wide, the rapid switching of the operating frequency may easily cause overshoot of the output voltage.

The second method is referred to as a progressive adjustment method. In the second method, when output voltage fluctuation occurs due to load variation, the sampled output voltage is compared with a set value to determine a deviation amount. When the deviation amount exceeds an allowable value, the operating frequency is adjusted. Through gradual adjustment over multiple switching cycles, a stable operating switching frequency of the converter is achieved. At the same time, PI regulation of the output voltage is performed in each switching cycle, so that the output voltage is stabilized. However, the second method has slow dynamic response of the converter due to factors such as sampling delay or program calculation delay. The converter may operate unstably during frequency transitions.

Therefore, there is a need of providing a control system and a control method of the control system to obviate the drawbacks encountered from the prior art.

### SUMMARY OF THE INVENTION

The present disclosure provides a control system and a control method of the control system. The control system of the present disclosure utilizes the detection module to adjust the output voltage of the converter according to the first electrical signal and the gain variation coefficient. The control module outputs a control signal to adjust the operating frequency of the converter. Consequently, the difference between the full-load operating frequency and the no-load operating frequency of the converter is less than the first preset frequency difference. Namely, the control system of the present disclosure meets the wide gain requirement of the converter under load conditions by adjusting the output voltage. Consequently, the converter switches the operating frequency with a reduced variation between the full-load operating frequency and the no-load operating frequency. The dynamic response speed is improved, the risk of output voltage overshoot is reduced, and adaptive capability is enhanced. Consequently, the converter has advantages of simplifying control, reducing cost and improving algorithm efficiency.

In accordance with an aspect of the present disclosure, a control system is provided. The control system includes a converter, a detection module and a control module. The converter is configured to provide an output voltage to a load and has a low-load gain curve, a high-load gain curve, a preset low-load operating frequency and a preset high-load operating frequency according to characteristics of the converter. A first load value of the load corresponding to the low-load gain curve is less than a second load value of the load corresponding to the high-load gain curve. The detection module is configured to sample the output voltage of the converter and an electrical signal. The electrical signal is a sampled signal reflecting an actual load value of the load. The control module is configured to adjust the output voltage of the converter according to the electrical signal and a gain variation coefficient and output a control signal to adjust an operating frequency of the converter. A difference between a full-load operating frequency and a no-load operating frequency of the converter is less than a first preset frequency difference. The gain variation coefficient is determined according to the low-load gain curve, the high-load gain curve, the preset low-load operating frequency and the preset high-load operating frequency.

In accordance with another aspect of the present disclosure, a control method for a converter system is provided. The converter system includes a load, a converter, a detection module and a control module. The converter is configured to provide an output voltage to the load. The control method includes the following steps. The converter is provided to have a low-load gain curve, a high-load gain curve, a preset low-load operating frequency and a preset high-load operating frequency according to characteristics of the converter. A first load value of the load corresponding to the low-load gain curve is less than a second load value of the load corresponding to the high-load gain curve. The output voltage of the converter and an electrical signal are sampled by the detection module. The electrical signal is a sampled signal reflecting an actual load value of the load. The output voltage of the converter is adjusted by the control module according to the electrical signal and a gain variation coefficient. A control signal is outputted to adjust an operating frequency of the converter. A difference between a full-load operating frequency and a no-load operating frequency of the converter is less than a first preset frequency difference. The gain variation coefficient is determined according to the low-load gain curve, the high-load gain curve, the preset low-load operating frequency and the preset high-load operating frequency.

The above contents of the present disclosure will become more readily apparent to those ordinarily skilled in the art after reviewing the following detailed description and accompanying drawings, in which:

### BRIEF DESCRIPTION OF THE DRAWINGS

FIG. 1 is a schematic block diagram illustrating a control system according to a first embodiment of the present disclosure;

FIG. 2 is a gain curve diagram of a converter of the control system of FIG. 1;

FIG. 3 is a detailed schematic circuit diagram of the control system of FIG. 1;

FIG. 4 is a timing diagram of the voltage and the current of the control system of FIG. 1;

FIG. 5 is a detailed schematic circuit diagram illustrating a control system according to a second embodiment of the present disclosure;

FIG. 6 is a detailed schematic circuit diagram illustrating a control system according to a third embodiment of the present disclosure; and

FIG. 7 is a flowchart illustrating a control method of the control system of the present disclosure.

### DETAILED DESCRIPTION OF THE PREFERRED EMBODIMENT

The present disclosure will now be described more specifically with reference to the following embodiments. It is to be noted that the following descriptions of preferred embodiments of this disclosure are presented herein for purpose of illustration and description only. It is not intended to be exhaustive or to be limited to the precise form disclosed.

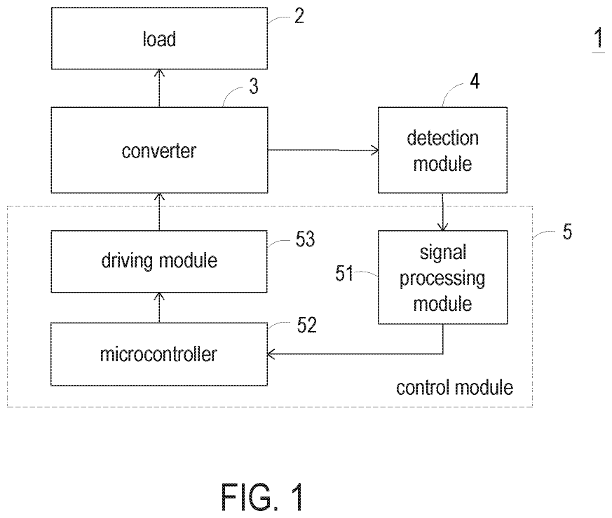

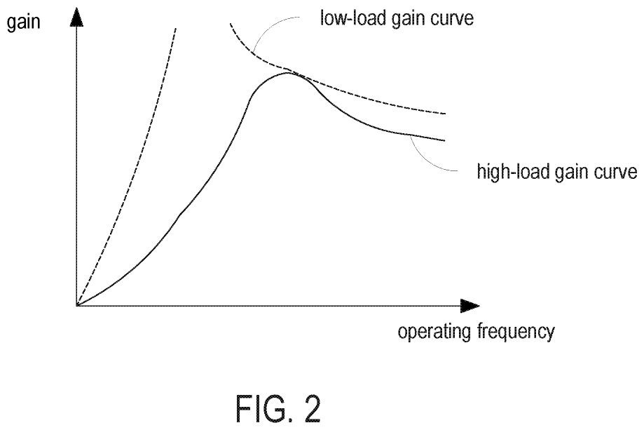

FIG. 1 is a schematic block diagram illustrating a control system according to a first embodiment of the present disclosure. FIG. 2 is a gain curve diagram of a converter of the control system of FIG. 1. As shown in FIG. 1, the control system 1 of the present disclosure includes a load 2, a converter 3, a detection module 4 and a control module 5. The converter 3 is but not limited to a resonant converter. The converter 3 is connected to the load 2. The converter 3 receives and converts an input voltage into an output voltage and an output current, and provides the output voltage and the output current to the load 2. The converter 3 has a low-load gain curve, a high-load gain curve, a preset low-load operating frequency and a preset high-load operating frequency according to the characteristics of the converter 3.

As shown in FIG. 2, the low-load gain curve and the high-load gain curve represent the gain-frequency relationship of the converter 3 at two different load values of the load 2, respectively. The load value corresponding to the low-load gain curve is less than the load value corresponding to the high-load gain curve. The gain curve represents a functional relationship between the gain and the operating frequency. In some embodiments, the low-load gain curve is corresponding to the gain curve of the converter 3 when the load value of the load 2 is in a no-load condition. The high-load gain curve is corresponding to the gain curve of the converter 3 when the load value of the load 2 is in a full-load condition. In one embodiment, the gain variation range of the converter 3 is less than or equal to 1. The low-load gain curve and the high-load gain curve are obtained by the converter 3 through a fundamental harmonic analysis method. The low-load gain curve and the high-load gain curve are calculated according to the following equation (1).

$$M ( λ , Q , fn ) = \frac{1}{\sqrt{{( fn * Q - \frac{Q}{fn} )}^{2} + {( 1 + \frac{1}{λ} - \frac{1}{λ * {fn}^{2}} )}^{2}}} \qquad ( 1 )$$

fn represents a normalized frequency. Q represents a quality factor. λ represents an inductance coefficient of the converter 3.

The preset low-load operating frequency and the preset high-load operating frequency represent the desired operating frequencies of the converter 3 at two different load values of the load 2, respectively. The load value corresponding to the preset low-load operating frequency is less than the load value corresponding to the preset high-load operating frequency. In some embodiments, the preset low-load operating frequency is corresponding to the desired operating frequency of the converter 3 under the no-load condition of the load 2, i.e., a no-load operating frequency. The preset high-load operating frequency is corresponding to the desired operating frequency of the converter 3 under the full-load condition of the load 2, i.e., a full-load operating frequency. The present disclosure is not limited thereto.

In this embodiment, the converter 3 determines a gain variation coefficient according to the low-load gain curve, the high-load gain curve, the preset low-load operating frequency and the preset high-load operating frequency. The unit of the gain variation coefficient is volt/ampere (V/A). The gain variation coefficient is positively correlated to a difference between a first gain and a second gain. In some embodiments, the gain variation coefficient is determined by multiplying the difference between the first gain and the second gain with a correction coefficient, but not limited thereto. The first gain is determined according to the low-load gain curve and the preset low-load operating frequency. For example, the first gain may be the gain corresponding to the preset low-load operating frequency on the low-load gain curve under the no-load condition of the load 2. The second gain is determined according to the high-load gain curve and the preset high-load operating frequency. For example, the second gain may be the gain corresponding to the preset high-load operating frequency on the high-load gain curve under the full-load condition of the load 2. Depending on application scenarios, the preset low-load operating frequency and the preset high-load operating frequency may be identical or different. For example, when the control system 1 requires only a single operating frequency, the preset low-load operating frequency and the preset high-load operating frequency are identical. When the control system 1 requires two different operating frequencies, the preset low-load operating frequency and the preset high-load operating frequency are different. A second preset frequency difference is existed between the preset low-load operating frequency and the preset high-load operating frequency. The second preset frequency difference is but not limited to 10 KHz.

Please refers to FIG. 1 again, the detection module 4 is connected to the converter 3 and samples the output voltage of the converter 3 and a first electrical signal of the load 2. The first electrical signal is a sampled signal reflecting an actual load value of the load 2. The first electrical signal may be a current signal of the converter 3. The unit of the first electrical signal is ampere. For example, the first electrical signal is an output current or an input current of the converter 3. Namely, the detection module 4 determines the load value of the load 2 according to the output current or the input current of the converter 3.

The control module 5 is connected to the detection module 4 and the converter 3. The control module 5 controls the converter 3 according to the first electrical signal provided by the detection module 4 and the gain variation coefficient of the converter 3. Consequently, the output voltage of the converter 3 is adjusted. A control signal is outputted to adjust the operating frequency of the converter 3. A difference between the full-load operating frequency and the no-load operating frequency of the converter 3 is less than a first preset frequency difference. The first preset frequency difference is but not limited to 20 kHz. Specifically, the operating frequency of the converter 3 under the high-load condition is less than the operating frequency of the converter 3 under the low-load condition. Consequently, the output voltage is reduced, and the operating frequency under the high-load condition is increased so as to approach the operating frequency under the low-load condition. In this embodiment, the control module 5 adjusts the output voltage by subtracting the output voltage to the product of the gain variation coefficient and the first electrical signal in every adjustment. The output voltage is reduced. Consequently, the full-load operating frequency is to approach the no-load operating frequency. The difference between the full-load operating frequency and the no-load operating frequency is reduced to be less than the first preset frequency difference.

From above, the control system 1 of the present disclosure utilizes the detection module 4 to adjust the output voltage of the converter 3 according to the first electrical signal and the gain variation coefficient. The control module 5 outputs a control signal to adjust the operating frequency of the converter 3. Consequently, the difference between the full-load operating frequency and the no-load operating frequency of the converter 3 is less than the first preset frequency difference. Namely, the control system 1 of the present disclosure meets the wide gain requirement of the converter under load conditions by adjusting the output voltage. Consequently, the converter 3 switches the operating frequency with a reduced variation between the full-load operating frequency and the no-load operating frequency. The dynamic response speed is improved, the risk of output voltage overshoot is reduced, and adaptive capability is enhanced. Consequently, the converter 1 has advantages of simplifying control, reducing cost and improving algorithm efficiency.

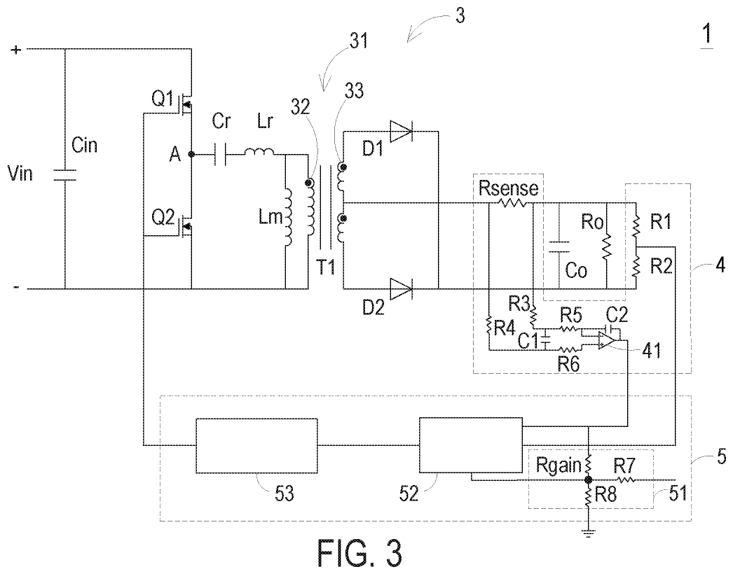

FIG. 3 is a detailed schematic circuit diagram of the control system of FIG. 1. As shown in FIGS. 1 and 3, in this embodiment, the converter 3 includes an input capacitor Cin, two transistors Q1 and Q2, a resonant capacitor Cr, a resonant inductor Lr, a magnetizing inductor Lm, a transformer 31, a first diode D1, a second diode D2, an output capacitor Co and an output resistor Ro. The input capacitor Cin receives an input voltage Vin. The two transistors Q1 and Q2 are connected in series and are connected in parallel with the input capacitor Cin. A connection point A is formed between the two transistors Q1 and Q2. The resonant capacitor Cr, the resonant inductor Lr and the magnetizing inductor Lm are connected in series between the connection point A and one end of the transistor Q2. The transformer 31 includes a primary winding 32 and a secondary winding 33. The primary winding 32 is connected to the magnetizing inductor Lm in parallel. An anode of the first diode D1 is connected to one end of the secondary winding 33. An anode of the second diode D2 is connected to the other end of the secondary winding 33. The detection module 4 is connected between a midpoint of the secondary winding 33 and the output capacitor Co. The output resistor Ro is connected to the output capacitor Co in parallel. In this embodiment, the converter 3 is a resonant converter. The resonant capacitor Cr and the resonant inductor Lr of the converter 3 are served as a resonant tank of the converter 3. The first electrical signal sampled by the detection module 4 is a current of the resonant tank. Namely, the detection module 4 determines the load value of the load 2 according to the current of the resonant tank.

The detection module 4 includes a sampling circuit and an operational amplifier circuit. As shown in FIG. 3, the detection module 4 further includes a first resistor R1, a second resistor R2, a sensing resistor Rsense, a first filter resistor R3, a second filter resistor R4, a third filter resistor R5, a fourth filter resistor R6, an amplifier 41, a first capacitor C1 and a second capacitor C2. The first resistor R1 and the second resistor R2 are connected in series and are connected to the output resistor Ro in parallel. A midpoint between the first resistor R1 and the second resistor R2 is served as an output voltage sampling point, and is connected to the control module 5. The sensing resistor Rsense is connected between a midpoint of the secondary winding 33 and one end of the output resistor Ro. The sensing resistor Rsense samples the output current to be served as the first electrical signal. The first filter resistor R3 and the third filter resistor R5 are connected in series between a first end of the sensing resistor Rsense and a first input end of the amplifier 41. The second filter resistor R4 and the fourth filter resistor R6 are connected in series between a second end of the sensing resistor Rsense and a second input end of the amplifier 41. One end of the first capacitor C1 is connected between the first filter resistor R3 and the third filter resistor R5, and the other end of the first capacitor C1 is connected between the second filter resistor R4 and the fourth filter resistor R6. The second capacitor C2 is connected between the first input end and a third end of the amplifier 41. The third end of the amplifier 41 is connected to the control module 5. The amplifier 41 converts the output current sampled by the sensing resistor Rsense into an output voltage signal. The output voltage signal is proportional to the output current.

In this embodiment, as shown in FIGS. 1 and 3, the control module 5 further includes a signal processing module 51, a microcontroller 52 and a driving module 53. The signal processing module 51 is connected between the detection module 4 and the microcontroller 52. The signal processing module 51 receives and processes the output voltage of the converter 3 and a first electrical signal of the load 2 sampled by the detection module 4, so as to transmit sampling results to the microcontroller 52. In this embodiment, the signal processing module 51 further includes a gain coefficient resistor Rgain, a first voltage dividing resistor R7 and a second voltage dividing resistor R8. The gain coefficient resistor Rgain is connected between a third end of the amplifier 41 and the microcontroller 52. One end of the first voltage dividing resistor R7 is connected to the midpoint between the first resistor R1 and the second resistor R2. The other end of the first voltage dividing resistor R7 is connected to the microcontroller 52. One end of the second voltage dividing resistor R8 is grounded. The other end of the second voltage dividing resistor R8 is connected to the microcontroller 52. The microcontroller 52 is connected between the signal processing module 51 and the driving module 53. The microcontroller 52 controls the driving module 53 to output corresponding driving signals for controlling the operation of the switching transistors Q1 and Q2 of the converter 3 according to the sampling results provided by the signal processing module 51. Consequently, the output voltage of the converter 3 is regulated.

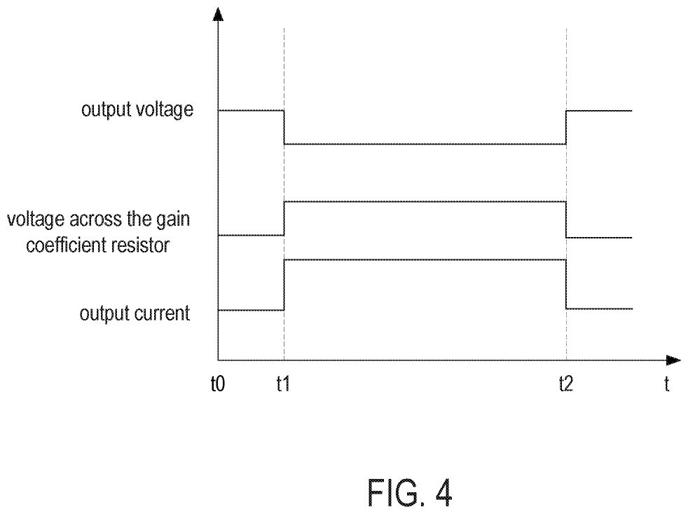

FIG. 4 is a timing diagram of the voltage and the current of the control system of FIG. 1. FIG. 4 shows the timing diagrams of the output voltage, the voltage across the gain coefficient resistor Rgain and the output current, respectively. As shown in FIG. 4, the electrical signal corresponding to the output voltage of the converter 3 sampled by the detection module 4 is divided by the first voltage dividing resistor R7 and the second voltage dividing resistor R8. The electrical signal corresponding to the output current sampled by the sensing resistor Rsense is divided by the gain coefficient resistor Rgain and the second voltage dividing resistor R8. A reference voltage in the control module 5 regulates the voltage across the second voltage dividing resistor R8 to remain constant. When the first electrical signal of the load 2 reflects an increasing of the load value of the load 2, the current through the load 2 is increased, as shown at time t1 in FIG. 4. Consequently, the electrical signal corresponding to the output current sampled by the sensing resistor Rsense is also increased. In this embodiment, the electrical signal corresponding to the output voltage sampled by the detection module 4 is increased at the second voltage dividing resistor R8, and the reference voltage remains constant. Consequently, the electrical signal corresponding to the output current sampled by the sensing resistor Rsense is reduced at the second voltage dividing resistor R8. When the load 2 is increased, the output voltage is reduced, so that the gain of the converter 3 under loading is close to a gain required for stable operation of the converter 3. Similarly, at time t2 in FIG. 4, when the load 2 is decreased, the current of the load 2 is decreased, the output voltage is increased, the voltage across the gain coefficient resistor Rgain is decreased, and the reference voltage remains constant. From above, when the converter 3 is in a stable state, variations of the load 2 cause variations of the output voltage and the switching frequency. Since different gains of the converter 3 is corresponding to different switching frequencies, the gain is directly adjusted first, and the switching frequency is further adjusted accordingly to ensure the stable state of the converter 3.

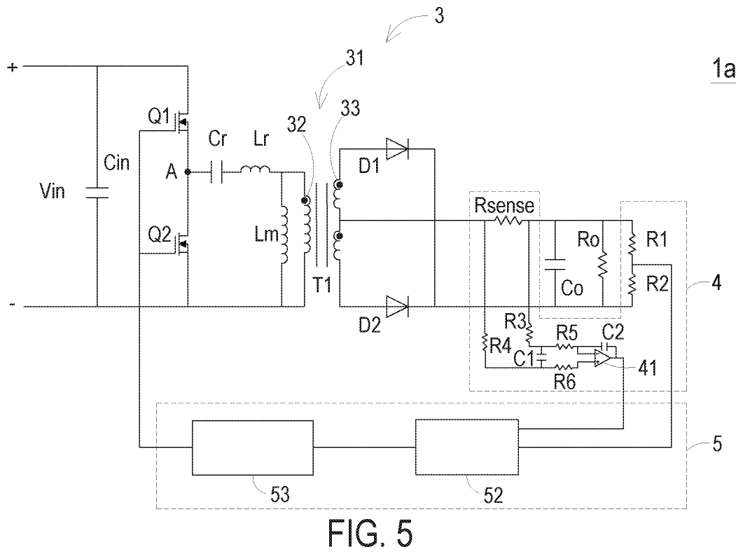

FIG. 5 is a detailed schematic circuit diagram illustrating a control system according to a second embodiment of the present disclosure. As shown in FIG. 5, the control module 5 of the control system 1a of the present embodiment only includes a microcontroller 52 and a driving module 53 without a signal processing module. The microcontroller 52 is directly connected to the midpoint between the first resistor R1 and the second resistor R2 so as to directly sample a voltage.

In some embodiments, the control module of the control system may only include the signal processing module and the microcontroller without the driving module. Consequently, the operation of the switching transistors Q1 and Q2 is directly controlled by the microcontroller.

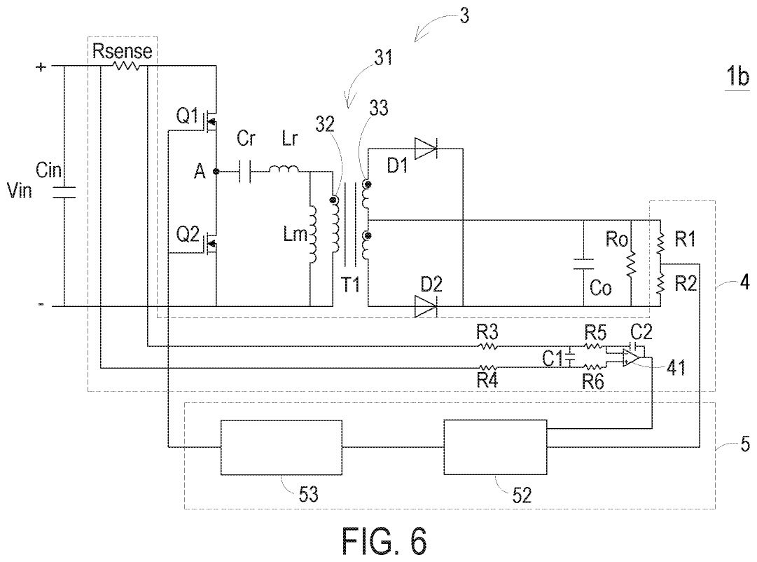

FIG. 6 is a detailed schematic circuit diagram illustrating a control system according to a third embodiment of the present disclosure. The control system 1b of this embodiment is similar to the control system 1 of FIG. 3. The sensing resistor Rsense of the detection module 4 of the control system 1 of FIG. 3 is connected between a midpoint of the secondary winding 33 and one end of an output resistor Ro to sample an output current as the first electrical signal. Compared with the control system 1 of FIG. 3, the sensing resistor Rsense of the detection module 4 of the control system 1b of this embodiment is connected between one end of an input capacitor Cin and one end of the switching transistor Q1 so as to sample an input current as the first electrical signal.

It should be understood that the control system of the present disclosure is not limited to sampling current by using a resistor. The sampled current may include not only input current, output current and resonant tank current, but also a winding current of a transformer.

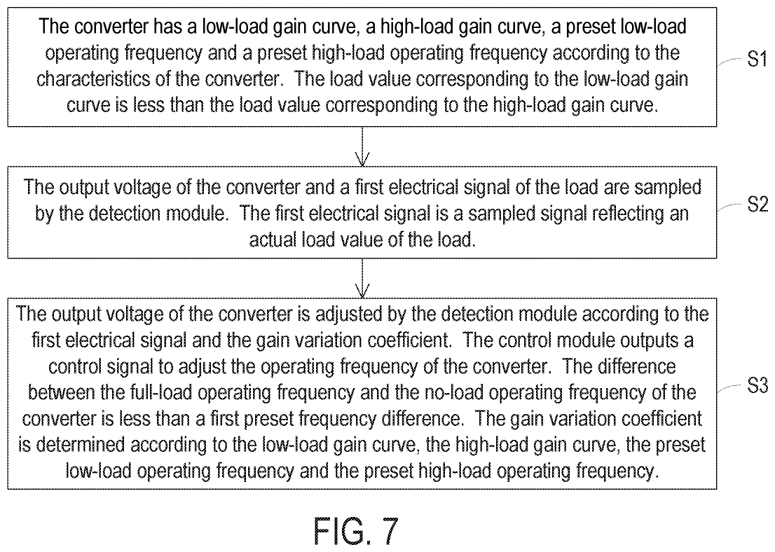

FIG. 7 is a flowchart illustrating a control method of the control system of the present disclosure. As shown in FIG. 7, firstly, a step S1 is performed. In the step S1, the converter 3 has a low-load gain curve, a high-load gain curve, a preset low-load operating frequency and a preset high-load operating frequency according to the characteristics of the converter 3. The load value corresponding to the low-load gain curve is less than the load value corresponding to the high-load gain curve. Then, a step S2 is performed. In the step S2, the output voltage of the converter 3 and a first electrical signal of the load 2 are sampled by the detection module 4. The first electrical signal is a sampled signal reflecting an actual load value of the load 2. Then, a step S3 is performed. In the step S3, the output voltage of the converter 3 is adjusted by the detection module 4 according to the first electrical signal and the gain variation coefficient. The control module 5 outputs a control signal to adjust the operating frequency of the converter 3. The difference between the full-load operating frequency and the no-load operating frequency of the converter 3 is less than a first preset frequency difference. The gain variation coefficient is determined according to the low-load gain curve, the high-load gain curve, the preset low-load operating frequency and the preset high-load operating frequency.

As mentioned above, the present disclosure discloses a control system and a control method of the control system. The control system of the present disclosure utilizes the detection module to adjust the output voltage of the converter according to the first electrical signal and the gain variation coefficient. The control module outputs a control signal to adjust the operating frequency of the converter. Consequently, the difference between the full-load operating frequency and the no-load operating frequency of the converter is less than the first preset frequency difference. Namely, the control system of the present disclosure has the wide gain requirement of the converter under load conditions by adjusting the output voltage. Consequently, the converter switches the operating frequency with a reduced variation between the full-load operating frequency and the no-load operating frequency. The dynamic response speed is improved, the risk of output voltage overshoot is reduced, and adaptive capability is enhanced. Consequently, the converter has advantages of simplifying control, reducing cost and improving algorithm efficiency.

While the disclosure has been described in terms of what is presently considered to be the most practical and preferred embodiments, it is to be understood that the disclosure needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A control system, comprising:
a converter configured to provide an output voltage to a load and has a low-load gain curve, a high-load gain curve, a preset low-load operating frequency and a preset high-load operating frequency according to characteristics of the converter, wherein a first load value of the load corresponding to the low-load gain curve is less than a second load value of the load corresponding to the high-load gain curve;
a detection module configured to sample the output voltage of the converter and an electrical signal, wherein the electrical signal is a sampled signal reflecting an actual load value of the load; and
a control module configured to adjust the output voltage of the converter according to the electrical signal and a gain variation coefficient and output a control signal to adjust an operating frequency of the converter, wherein a difference between a full-load operating frequency and a no-load operating frequency of the converter is less than a first preset frequency difference, wherein the gain variation coefficient is determined according to the low-load gain curve, the high-load gain curve, the preset low-load operating frequency and the preset high-load operating frequency.

2. The control system according to claim 1, wherein the gain variation coefficient is determined according to a first gain and a second gain, the gain variation coefficient is positively correlated to a difference between the first gain and the second gain, wherein the first gain is determined according to the low-load gain curve and the preset low-load operating frequency, and the second gain is determined according to the high-load gain curve and the preset high-load operating frequency.

3. The control system according to claim 1, wherein the first load value of the load corresponding to the low-load gain curve is under a no-load condition, and the second load value of the load corresponding to the high-load gain curve is under a full-load condition.

4. The control system according to claim 1, wherein the preset low-load operating frequency and the preset high-load operating frequency are identical.

5. The control system according to claim 1, wherein a second preset frequency difference is existed between the preset low-load operating frequency and the preset high-load operating frequency.

6. The control system according to claim 1, wherein the control module adjusts the output voltage by subtracting the output voltage to the product of the gain variation coefficient and the electrical signal, wherein the unit of the gain variation coefficient is volt/ampere, the electrical signal is a current signal of the converter, and the unit of the electrical signal is ampere.

7. The control system according to claim 1, wherein the electrical signal is an output current or an input current of the converter.

8. The control system according to claim 1, wherein the converter is a resonant converter and includes a resonant tank, and the electrical signal is a current of the resonant tank.

9. The control system according to claim 1, wherein the first preset frequency difference is 20 KHz.

10. The control system according to claim 1, wherein a gain variation range of the converter is less than or equal to 1.

11. A control method for a converter system, the converter system comprising a load, a converter, a detection module and a control module, the converter being configured to provide an output voltage to the load, and the control method comprising:
providing the converter having a low-load gain curve, a high-load gain curve, a preset low-load operating frequency and a preset high-load operating frequency according to characteristics of the converter, wherein a first load value of the load corresponding to the low-load gain curve is less than a second load value of the load corresponding to the high-load gain curve;
sampling the output voltage of the converter and an electrical signal by the detection module, wherein the electrical signal is a sampled signal reflecting an actual load value of the load; and
adjusting the output voltage of the converter by the control module according to the electrical signal and a gain variation coefficient, and outputting a control signal to adjust an operating frequency of the converter, and a difference between a full-load operating frequency and a no-load operating frequency of the converter is less than a first preset frequency difference, wherein the gain variation coefficient is determined according to the low-load gain curve, the high-load gain curve, the preset low-load operating frequency and the preset high-load operating frequency.

12. The control method according to claim 11, wherein the control method comprises:
determining the gain variation coefficient according to a first gain and a second gain, wherein the gain variation coefficient is positively correlated to a difference between the first gain and the second gain, the first gain is determined according to the low-load gain curve and the preset low-load operating frequency, and the second gain is determined according to the high-load gain curve and the preset high-load operating frequency.

13. The control method according to claim 11, wherein the first load value of the load corresponding to the low-load gain curve is under a no-load condition, and the second load value of the load corresponding to the high-load gain curve is under a full-load condition.

14. The control method according to claim 11, wherein the control method comprises:
determining the preset low-load operating frequency and the preset high-load operating frequency being identical.

15. The control method according to claim 11, wherein the control method comprises:
determining a second preset frequency difference existed between the preset low-load operating frequency and the preset high-load operating frequency.

16. The control method according to claim 11, wherein the control method comprises:
adjusting the output voltage by the control module by subtracting the output voltage to the product of the gain variation coefficient and the electrical signal, wherein the unit of the gain variation coefficient is volt/ampere, the electrical signal is a current signal of the converter, and the unit of the electrical signal is ampere.

17. The control method according to claim 11, wherein the electrical signal is an output current or an input current of the converter.

18. The control method according to claim 11, wherein the converter is a resonant converter and includes a resonant tank, and the electrical signal is a current of the resonant tank.

19. The control method according to claim 11, wherein the first preset frequency difference is 20 KHz.
